(19) United States
(12) Patent Application Publication
(10) Pub. No.: US 2016/0262284 A1
(43) Pub. Date: Sep. 8, 2016

(54) COLD PLATE STRUCTURE

(71) Applicant: ASIA VITAL COMPONENTS (CHINA) CO., LTD., Taipei City (TW)

(72) Inventors: Guo-Hui Ii, Shenzhen City (CN); Dan-Jun Chen, Shenzhen City (CN)

(21) Appl. No.: 14/636,194

(22) Filed: Mar. 3, 2015

(51) Int. Cl. H05K 7/20

(52) U.S. Cl. CPC H05K 7/202

(57) ABSTRACT

A cold plate structure comprises a plate body and a pipe. The plate body has a first side and a second side. A groove is formed on the second side. The pipe is embedded in the groove correspondingly. The pipe is filled with a gas. By means of the design of the present invention, the oxidation on the inner wall of the pipe can be avoided. Consequently, the operating efficiency is significantly increased and the manufacturing cost is reduced.

### BACKGROUND OF THE INVENTION

1. Field of the Invention

The present invention relates to a cold plate structure and, in particular, to a cold plate structure, which can avoid the oxidation on the inner wall of the pipe, increase the operating efficiency, and reduce the manufacturing cost.

2. Description of Prior Art

The water-cooling technique as a high efficient heat-dissipation program applied to electronic devices has become more and more popular. The cold plate as an important component in a water-cooling heat-dissipation system is a key and essential part. The quality level of the cold plate design determines key technical indexes of a heat-dissipation system, such as heat-dissipation efficiency and reliability.

The traditional cold plate is formed by casting liquid metal at high temperature into a mold having a pipe and then cooling down. Because the high-temperature liquid metal covers the pipe during casting, the temperature of the pipe will increase rapidly close to that of the liquid metal. In general, there is no protection measures on the casting process of the pipe in which residual air will remain in the pipe. At high temperatures, the pipe will react with the oxygen in the residual air and the inner wall of the pipe is then oxidized, resulting in a thin oxide layer attached on the inner wall of the pipe.

In the prior art, a special solution can be used to remove the thin oxide layer. However, the pipe has a bent shape, causing difficulty in the removal process of the thin oxide layer. Besides, it is not sure whether there is a residue of the solution remaining in the pipe when the special solution is used to remove the thin oxide layer and it is more difficult to make sure that the thin oxide layer can be completely removed. If there is any residue of the oxide layer remaining in the pipe, the oxide layer will contaminate the liquid coolant in the water-cooling system after the cold plate operates for a long time, which may damage other precise components, block the water channel system, and then affect the normal operation of the whole system.

Further, if the residue of the oxide layer remains in the deep portion of the pipe, it cannot be identified by eyes to be removed completely. It is necessary to use a specific device to scan the removal result, which increases the manufacturing cost and complicates the manufacturing process.

In summary, the prior art suffers from the following disadvantages:

1. The thin oxide layer cannot be removed completely.

2. Higher manufacturing cost.

3. Decreased operating efficiency.

4. Normal operation of the water-cooling system is affected by the thin oxide layer.

Therefore, how to overcome the above problems and disadvantages of the prior art is the focus which the inventor and the related manufacturers in this industry have been devoting themselves to.

### SUMMARY OF THE INVENTION

Thus, to effectively overcome the above problems, the main objective of the present invention is to provide a cold plate structure, which can avoid the oxidation on the inner wall of the pipe.

Another objective of the present invention is to provide a cold plate structure, which can significantly increase the operating efficiency.

Still another objective of the present invention is to provide a cold plate structure, which can reduce the manufacturing cost.

Yet still another objective of the present invention is to provide a manufacturing method of a cold plate structure, which can avoid the oxidation on the inner wall of the pipe.

Yet still another objective of the present invention is to provide a manufacturing method of a cold plate structure, which can significantly increase the operating efficiency.

Yet still another objective of the present invention is to provide a manufacturing method of a cold plate structure, which can reduce the manufacturing cost.

To achieve the above objectives, the present invention provides a cold plate structure, which comprises a plate body and a pipe. The plate body has a first side and a second side; a groove is formed on the second side. The pipe is embedded in the groove correspondingly; the pipe is filled with a gas.

To achieve the above objectives, the present invention provides a manufacturing method of a cold plate structure, which comprises the steps of:

(a) providing a pipe and using vacuum equipment to vacuum the pipe;

(b) providing gas filling equipment to fill the pipe with a gas;

(c) providing a sealing device to seal the filled pipe; and

(d) placing the pipe in a mold and providing a liquid metal cast in the mold and cooling down to form a cold plate structure.

By means of the cold plate structure and the manufacturing method thereof of the present invention, the pipe is vacuumed and then is filled with the gas, which can avoid the oxidation of the inner wall of the pipe to form a thin oxide layer. As a result, the problem of the residue of the oxide layer of the traditional cold plate remaining in the pipe can be improved to prevent the water-cooling system from be affected by the thin oxide layer. Also, the operating efficiency can be increased significantly and the manufacturing cost can be reduced.

### BRIEF DESCRIPTION OF DRAWING

FIG. 1 is a perspective exploded view of the cold plate structure according to the first embodiment of the present invention;

FIG. 2 is a perspective assembled view of the cold plate structure according to the first embodiment of the present invention;

FIG. 3 is a schematic view of the manufacturing method of the cold plate structure according to the first embodiment of the present invention;

FIG. 4 is a perspective exploded view of the manufacturing method of the cold plate structure according to the first embodiment of the present invention;

FIG. 5 is a perspective assembled view of the manufacturing method of the cold plate structure according to the first embodiment of the present invention;

FIG. 6 is a cross-sectional view of the manufacturing method of the cold plate structure according to the first embodiment of the present invention; and

FIG. 7 is a flow chart of the manufacturing method of the cold plate structure according to the first embodiment of the present invention.

### DETAILED DESCRIPTION OF THE INVENTION

The above objectives of the present invention and the features of structure and function of the present invention are described below according to the preferred embodiments in figures.

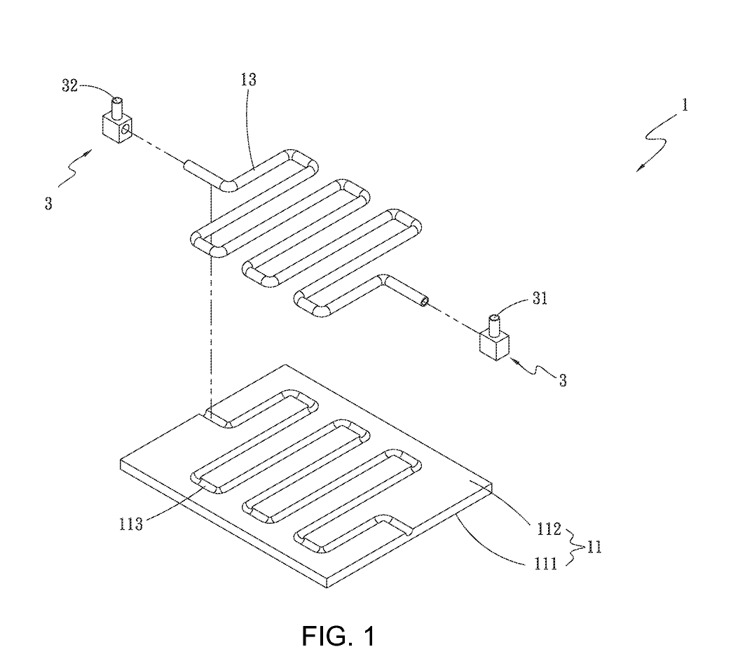

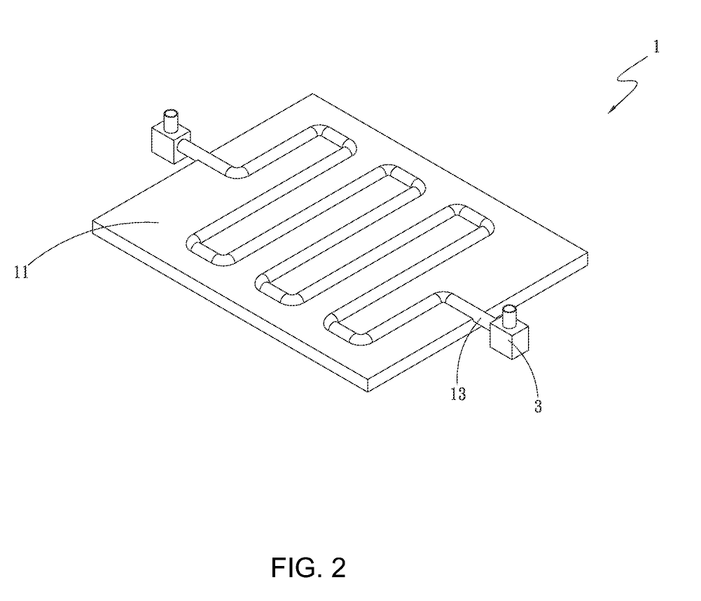

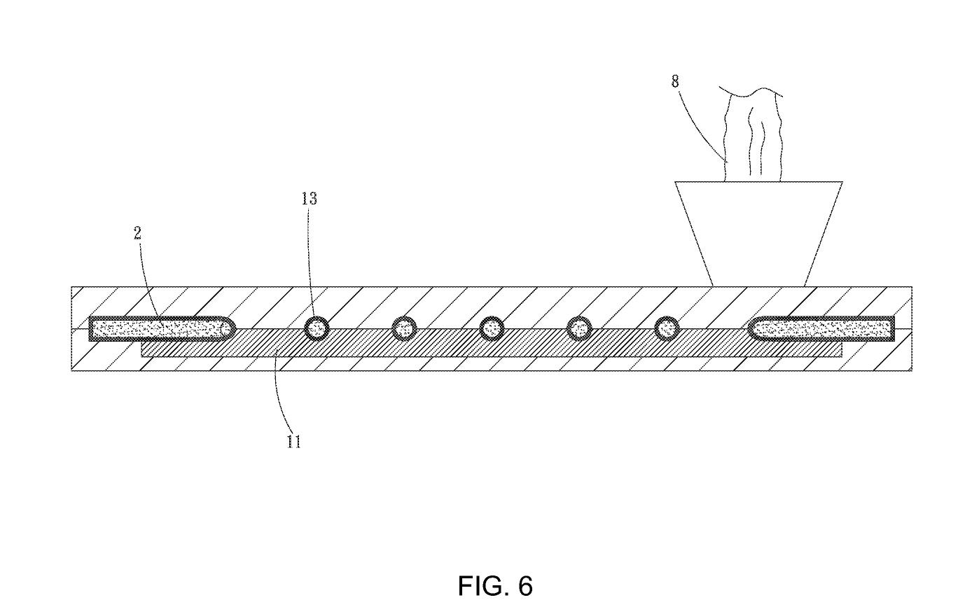

Please refer to FIGS. 1, 2, and 6, which are the perspective exploded view, the perspective assembled view, and the cross-sectional view of the present invention, respectively. As shown in these figures, a cold plate structure 1 comprises a plate body 11 and a pipe 13. The plate body 11 has a first side 111 and a second side 112 opposite to the first side 111. A groove 113 is formed on the second side 112.

The pipe 13 is embedded in the groove 113 correspondingly. The pipe 13 is filled with a gas 2. The gas 2 is selected from the group consisting of hydrogen, nitrogen, and any other gas (except for air).

The cold plate structure 1 further comprises an adapter 3 which has an inlet 31 and an outlet 32. The inlet 31 and the outlet 32 are individually connected to two ends of the pipe 13.

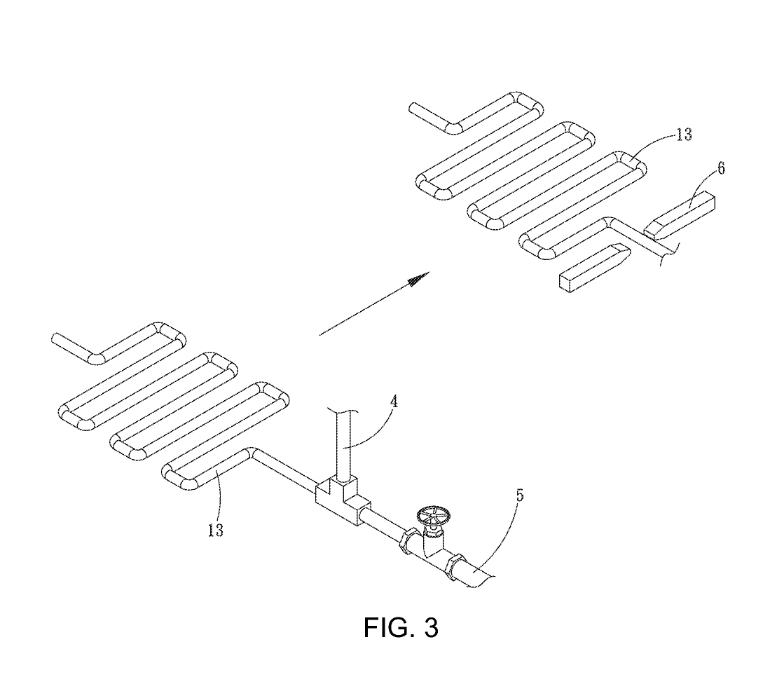

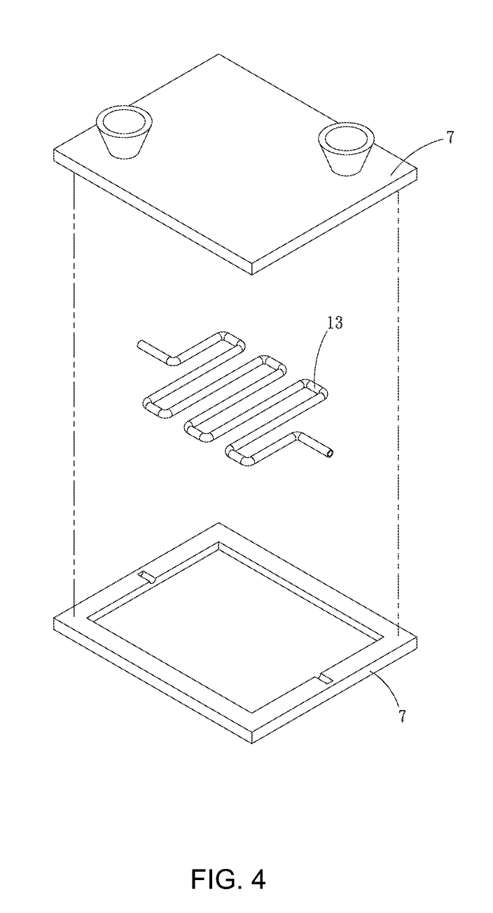

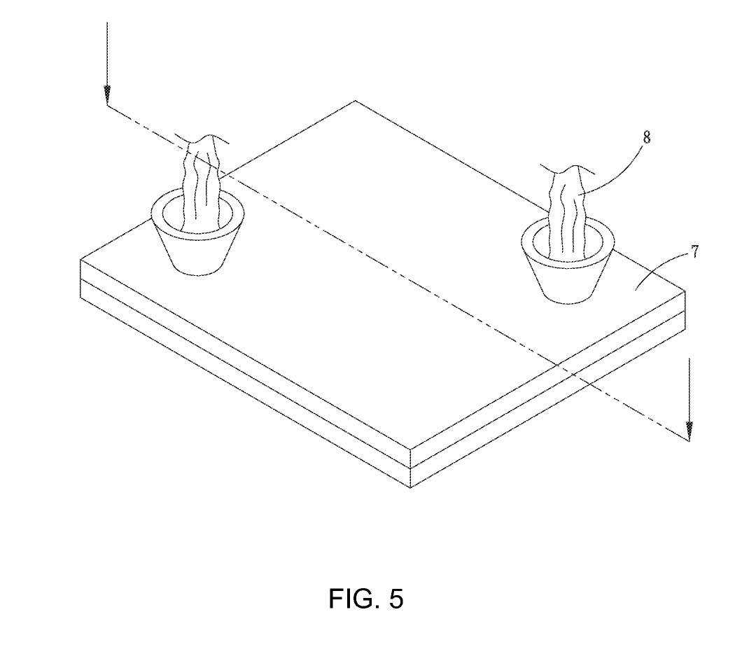

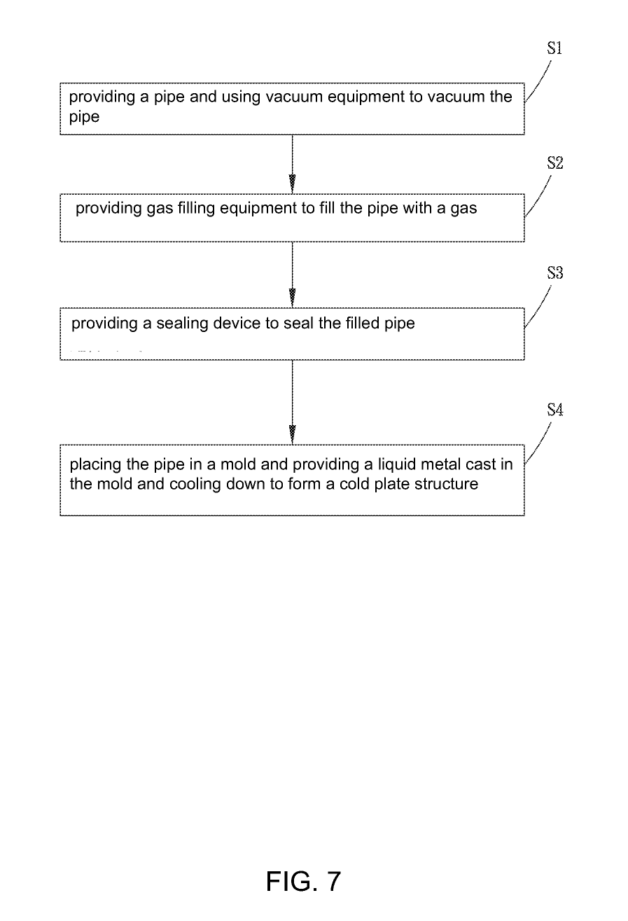

Please refer to FIGS. 3-7, which are the schematic view, the perspective exploded view, the perspective assembled view, the cross-sectional view, and the flow chart of the manufacturing method of the cold plate structure according to the first embodiment of the present invention, respectively, and refer to FIG. 1. As shown in the figures, a manufacturing method of the cold plate structure comprises the steps of:

S1: providing a pipe and using vacuum equipment to vacuum the pipe.

A pipe 13 is provided and then vacuum equipment 4 is used to vacuum the pipe 13.

S2: providing gas filling equipment to fill the pipe with a gas.

After the pipe 13 is vacuumed, gas filling equipment 5 is used to fill the pipe 13 with a gas 2. The gas 2 can be hydrogen, nitrogen, or any other gas.

S3: providing a sealing device to seal the filled pipe.

Then, the pipe 13 filled with the gas 2 is sealed by a sealing device 6.

S4: placing the pipe in a mold and providing a liquid metal cast in the mold and cooling down to form a cold plate structure.

Finally, the sealed pipe 13 is placed in a mold 7 and a liquid metal 8 is provided and cast in the mold 7 such that the liquid metal 8 covers the pipe 13. After cooling down, the cold plate structure 1 is formed.

Besides the cold plate structure 1 further comprises an adapter 3 which has an inlet 31 and an outlet 32. The inlet 31 and the outlet 32 are individually connected to two ends of the pipe 13.

By means of the designs of the cold plate structure and the manufacturing method thereof of the present invention, during the manufacturing process of the cold plate structure 1, vacuum equipment 4 is first used to vacuum the pipe 13. Then, after the pipe 13 is vacuumed, the gas filling equipment 5 is used to fill the pipe 13 with the gas 2. The gas 2 can be hydrogen, nitrogen, or at least one gas which does not react with oxygen in the pipe 13. Next, the pipe 13 filled with the gas 2 is sealed. Finally, the pipe 13 is placed in the mold 7 and the liquid metal 8 is cast in the mold 7 such that the liquid metal 8 covers the pipe 13. Because the pipe 13 is vacuumed and filled with the gas 2, when the high-temperature liquid metal 8 contacts the pipe 13, the oxidation will not occur. Thus, the traditional thin oxide layer will not occur inside the pipe 13 and the problem of the residue of the oxide layer of the traditional cold plate remaining in the pipe can be improved to prevent the normal operation of the water-cooling system from be affected by the thin oxide layer.

In addition, the problem of excessive cost and time, which is caused by using a specific device to scan the removal result to determine if there is any residue of the oxide layer remaining in the pipe, can be improved. Consequently, the operating efficiency is significantly increased and the manufacturing cost is significantly reduced.

In summary, compared with the prior art, the present invention has the following advantages.

1. The oxidation on the inner wall of the pipe is avoided.

2. The problem of the traditional oxide layer residue is improved.

3. The operating efficiency is significantly increased.

4. The manufacturing cost is significantly reduced.

5. Normal operation of the water-cooling system is not affected by the oxide layer.

The present invention has been described in detail above. It will be understood that the above description is only a preferred embodiments of the present invention, which should not limit the scope of the present invention. All equivalent variations and modifications according to the claimed scope of the present invention should be embraced by the scope of the appended claims of the present invention.

What is claimed is:

1. A cold plate structure, comprising:
a plate body having a first side and a second side, wherein a groove is formed on the second side; and
a pipe embedded in the groove correspondingly, wherein the pipe is filled with a gas.

2. The cold plate structure according to claim 1, wherein the gas is selected from the group consisting of hydrogen, nitrogen, and any other gas.

3. The cold plate structure according to claim 1, further comprising an adapter which has an inlet and an outlet, wherein the inlet and the outlet are individually connected to two ends of the pipe.
